(19) United States
(12) Patent Application Publication
(10) Pub. No.: US 2008/0047738 A1
(43) Pub. Date: Feb. 28, 2008

(54) Printed wiring board and printed circuit board

(75) Inventor: Tomoya Kanehira, Yamagata (JP)

Correspondence Address: NIXON & VANDERHYE, PC, 901 NORTH GLEBE ROAD, 11TH FLOOR, ARLINGTON, VA, 22203, US

(73) Assignees: Pioneer Corporation, Tokyo (JP); Tohoku Pioneer Corporation, Tendo-shi (JP)

(21) Appl. No.: 11/878,787

(22) Filed: Jul. 26, 2007

(30) Foreign Application Priority Data
Jul. 26, 2006 (JP) 2006-202826

(51) Int. Cl. H05K 1/03

(52) U.S. Cl. 174/255

(57) ABSTRACT

A printed wiring board is used as a printed circuit board of various kinds of electronic devices, and has a part on which a coil is mounted. A metallic pattern area such as a copper foil is formed in a coil vicinity area including the part on which said at least coil is mounted, on the printed wiring board. The metallic pattern area is divided into plural areas in a direction of a coil current flowing in the coil. Thereby, a loop current is not generated in the same direction as that of the coil current in the metallic pattern area.

### BACKGROUND OF THE INVENTION

1. Field of the Invention

The present invention relates to a printed wiring board including a conductive metallic pattern.

2. Description of Related Art

Various kinds of electronic devices include printed circuit boards on which various kinds of electronic parts are arranged on printed wiring boards having metallic patterns such as a copper foil. As an example of the printed circuit boards, a network circuit provided between an amplifier and a speaker of an acoustic reproduction device is disclosed in Japanese Patent Application Laid-open under No. 2004-187233.

A coil serving as an element forming a filter is sometimes provided on the above printed circuit board. In the coil, a current flows, and thereby a magnetic field is generated. Correspondently, a loop current is generated in the metallic pattern provided in the vicinity of the coil on the printed wiring board. In this case, if the loop current is generated in the same direction as that of the current flowing in the coil, the loop current affects an inductance of the coil. In addition, a force is generated by the magnetic field generated by the coil and the loop current generated in the metallic pattern, which sometimes causes minute vibration of the printed wiring board.

An example of the electronic device which reduces noise by arranging the coil perpendicularly to the printed wiring board is disclosed in Published Japanese Translation of PCT International Publication for Patent Application No. 2002-540485.

### SUMMARY OF THE INVENTION

The present invention has been achieved in order to solve the above problem. It is an object of this invention to reduce an effect of a loop current generated in a metallic pattern provided in the vicinity of a coil, on a printed wiring board on which the coil is mounted.

According to one aspect of the present invention, there is provided a printed wiring board including: a coil mounting part on which a coil is mounted; and a metallic pattern area which is provided in a coil vicinity area including the coil mounting part, wherein the metallic pattern area is divided into plural areas in a direction of a coil current flowing in the coil.

The above printed wiring board is used as a printed circuit board of various kinds of electronic devices, and includes the part on which the coil is mounted. The metallic pattern area such as a copper foil is formed in the coil vicinity area including the part on which said at least coil is mounted, on the printed wiring board. The metallic pattern area is divided into the plural areas in the direction of the coil current flowing in the coil. Thereby, since the loop current is not generated in the same direction as that of the coil current in the metallic pattern area, a problem caused due to the generation of the loop current can be prevented.

In a manner of the above printed wiring board, the metallic pattern area may include grooves which intersect with the direction of the coil current and which segment the plural areas. In this manner, the grooves formed by removing the metal are provided in the metallic pattern area, and segment the plural areas. Since the grooves are provided to intersect with the direction of the metallic coil, the passage of the loop current in the same direction as that of the coil current is cut, and the generation of the loop current is prevented.

In another manner of the above printed wiring board, the metallic pattern area may be divided into plural areas in a direction from a center of the coil to an outer side thereof. In this manner, since the metallic pattern area is also divided in the direction to the outer side of the coil, the generation of the loop current having a small diameter can be also prevented.

In an example of the above printed wiring board, the metallic pattern area may include a terminal area to which a terminal of the coil is conductively fixed.

According to another aspect of the present invention, there is provided a printed circuit board including: a coil; and a printed wiring board on which a metallic pattern area is provided in a coil vicinity area including a coil mounting part on which the coil is mounted, wherein the metallic pattern area is divided into plural areas in a direction of a coil current flowing in the coil.

The above printed circuit board is used as the printed circuit board of various kinds of electronic devices, and includes the printed wiring board on which the coil is mounted. The metallic pattern area such as the copper foil is formed in the coil vicinity area including the part on which said at least coil is mounted, on the printed wiring board. The metallic pattern area is divided into the plural areas in the direction of the coil current flowing in the coil. Thereby, since the loop current is not generated in the same direction as that of the coil current in the metallic pattern area, the problem caused due to the generation of the loop current can be prevented.

The nature, utility, and further features of this invention will be more clearly apparent from the following detailed description with respect to preferred embodiment of the invention when read in conjunction with the accompanying drawings briefly described below.

### BRIEF DESCRIPTION OF THE DRAWINGS

FIG. 1 shows a plan view showing an appearance of a network circuit according to an embodiment of the present invention;

FIG. 2 is a plan view of a printed wiring board according to the embodiment;

FIG. 3 is a diagram showing a coil current flowing in a choke coil;

FIG. 4 is a diagram showing an example of a general loop current;

FIG. 5 is a cross-sectional view of the choke coil and the printed wiring board;

FIG. 6 is a diagram for explaining a principle of suppressing the loop current according to the embodiment; and

FIG. 7 is a plan view of the printed wiring board according to a modification.

### DETAILED DESCRIPTION OF THE PREFERRED EMBODIMENTS

Now, a preferred embodiment of the present invention will be described below, with reference to the attached drawings.

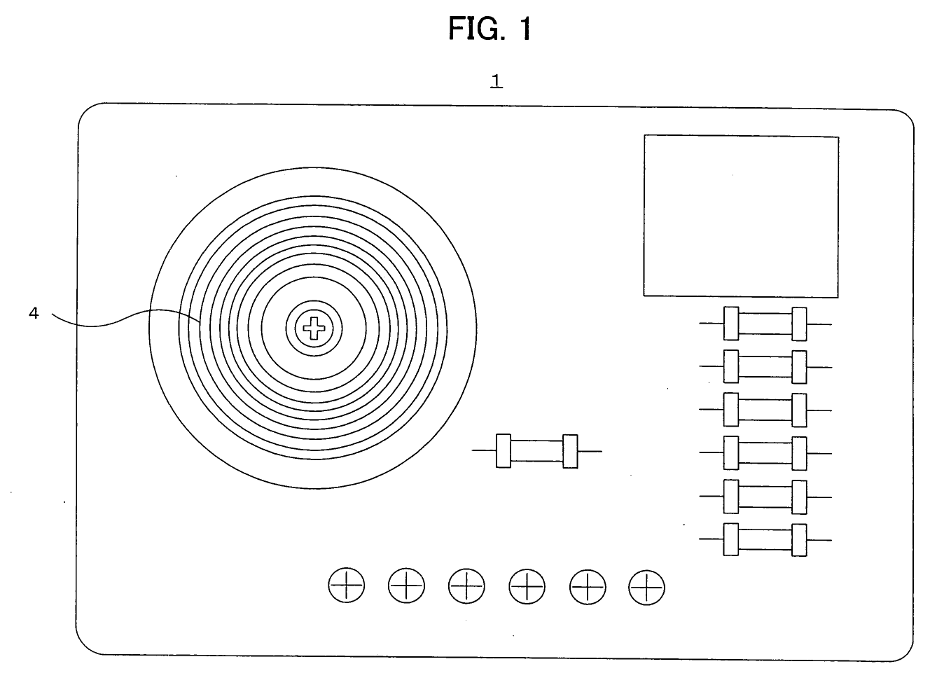

FIG. 1 shows an appearance of a network circuit according to an embodiment of the present invention. A network circuit 1 is used for an acoustic reproduction system, and is generally provided between a speaker and an amplifier for amplifying and outputting a sound signal. Namely, the sound signal (source signal) from the amplifier is inputted into the network circuit 1, and the sound signal supplied to the speaker is outputted from the network circuit 1. The network circuit is an example of the circuit including the coil, and application of the present invention is not limited to the circuit of this kind.

As schematically shown in FIG. 1, the network circuit 1 includes a choke coil 4 and various kinds of electronic devices such as a resistor and a switch. In this embodiment, the metallic pattern on the printed wiring board in the vicinity of the choke coil is particularly characterized.

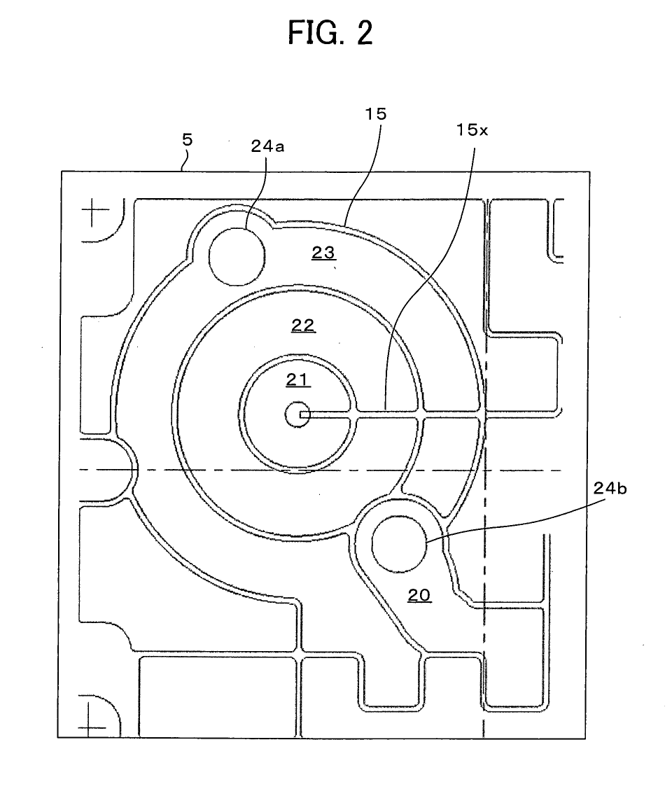

FIG. 2 shows a plan view of a printed wiring board 5 provided in the network circuit 1. In FIG. 2, an area on which the choke coil is mounted, on the printed wiring board 5, is particularly enlarged and shown. Actually, various kinds of elements and terminals other than the choke coil are mounted on the printed wiring board 5.

In FIG. 2, plural metallic pattern areas 20 to 23, made of a conductive metal such as the copper foil, are provided on the printed wiring board 5. The metallic pattern areas 20 to 23 correspond to coil mounting parts of the present invention, and the metallic pattern areas 20 to 23 and a metallic pattern area within a predetermined range on the outer side thereof correspond to the coil vicinity areas.

The respective metallic pattern areas 20 to 23 are segmented by plural grooves 15. The part of each groove 15 is formed by removing the metallic pattern linearly with a predetermined width. Thereby, each of the metallic pattern areas 20 to 23 is formed into an island shape surrounded by each of the grooves 15.

The plural island-shaped metallic pattern areas 20 to 23 have a function to maintain the strength of the printed wiring board 5. Since the metallic pattern areas 21 and 22 shown in FIG. 2 do not contribute to input/output of the signal into/from the choke coil 4, they can be removed in consideration of the circuit configuration. However, if the metallic pattern areas 21 and 22 are removed, the strength of the entire printed wiring board 5 is reduced. Thus, the metallic pattern areas are also left in the areas having no relation with the input/output of the signal.

In addition, the plural metallic pattern areas 20 to 23 also have a vibration suppressive effect of the printed wiring board. When the sound current flows into the choke coil 4, the vibration which is generated due to a relation with the magnetic field is transmitted to the printed wiring board 5. However, since the base material and the metallic foil of the printed wiring board 5 are made of different materials, the vibration frequencies of them are different, which brings an effect of mutually reducing the vibration.

Each of the metallic pattern areas 20 to 23 can be formed in such a method that the metal is partly removed from a large metallic area initially provided on the printed wiring board by etching and the plural grooves 15 are formed. However, the forming method of the grooves is not particularly limited in the present invention.

In FIG. 2, terminal parts 24a and 24b for soldering input/output terminals of the choke coil 4 are formed in the metallic pattern area 23. One of the terminal parts 24a and 24b is the input terminal, and the other is the output terminal. The terminal part 24a is electrically connected to the metallic pattern area 23, and the terminal part 24b is electrically connected to the metallic pattern area 20.

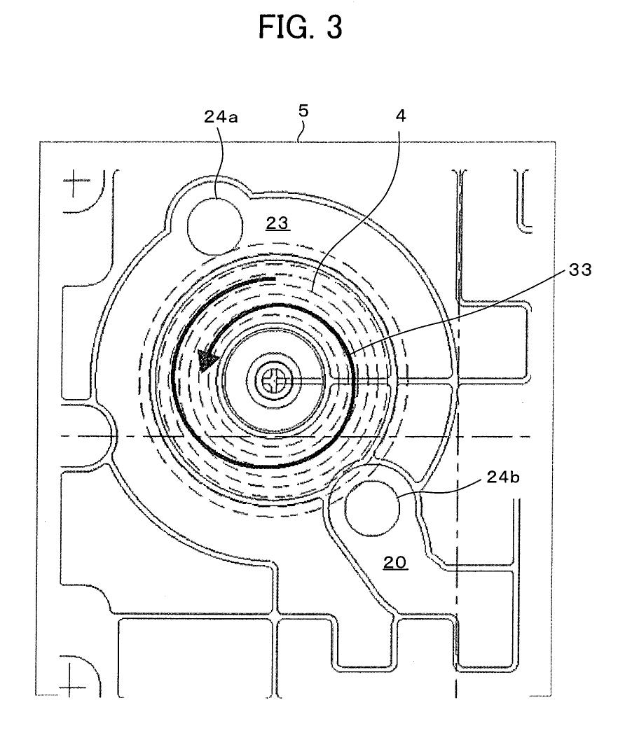

Next, a description will be given of the current flowing in the choke coil. FIG. 3 shows such a state that the choke coil 4 is mounted on the printed wiring board 5. The sound current from the amplifier flows into the choke coil 4. The direction of the current (hereinafter, also referred to as “coil current”) flowing in the choke coil 4 is shown by an arrow 33. As shown, the coil current flows in the direction in which a wire forming the choke coil is wound around, generally in a circumferential direction of the choke coil.

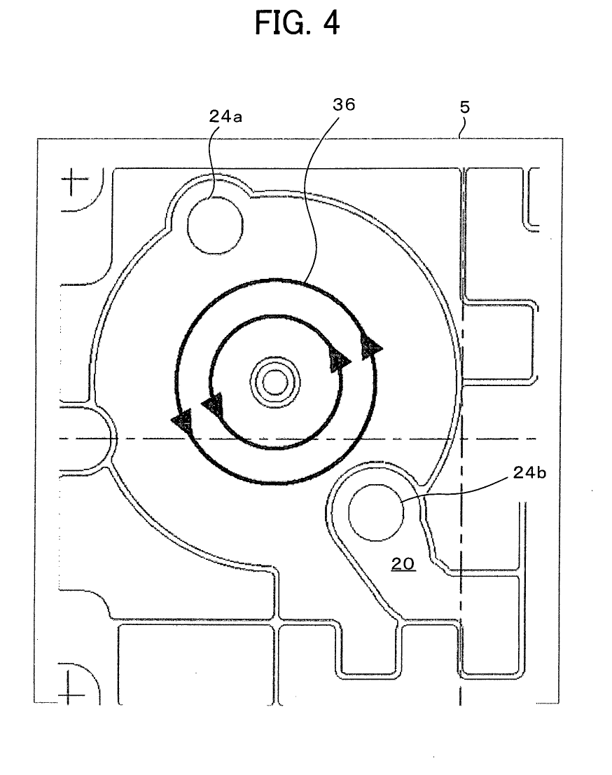

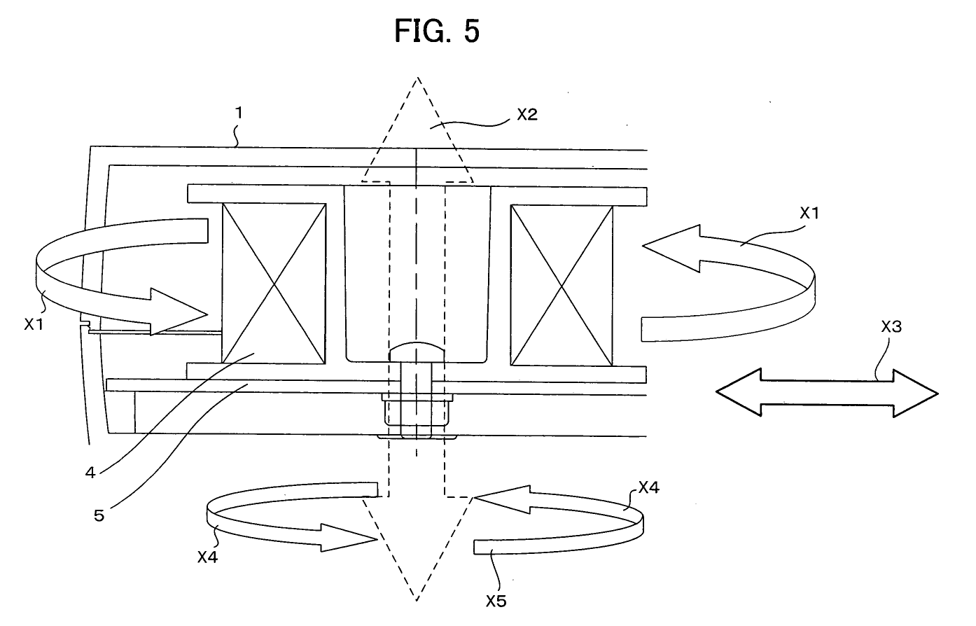

Next, a description will be given of the loop current generated in the metallic pattern area. FIG. 4 shows an example of the loop current in such a case that the metallic pattern area is not divided, unlike this embodiment. As described above, since the metallic pattern area is formed in the area in the vicinity of the choke coil 4 on the printed wiring board 5, i.e., under the choke coil and thereabout, the induced current flows in the metallic pattern area. If the metallic pattern area is large as shown in FIG. 5, the induced current in a loop shape (i.e., referred to as “loop current”) is generated, as shown by an arrow 36. If the loop current is generated in the same direction as that of the coil current flowing in the choke coil 4, the inductance of the choke coil 4 is affected.

FIG. 5 is a diagram for explaining the effect caused due to the loop current, and is a cross-sectional view of the choke coil 4 and the printed wiring board 5 in the area including the choke coil 4. When the coil current flows in the choke coil 4 in the direction of an arrow X1, the magnetic field is generated in the direction of an arrow X2. Meanwhile, when the loop current is generated in the metallic pattern area of the printed wiring board 5 in the direction of an arrow X4, the vibration is generated in the direction of an arrow X3 by the loop current and the magnetic field generated by the choke coil 4. Additionally, the loop current generated in the metallic pattern area works so that the inductance of the choke coil 4 increases or decreases, which affects the inductance.

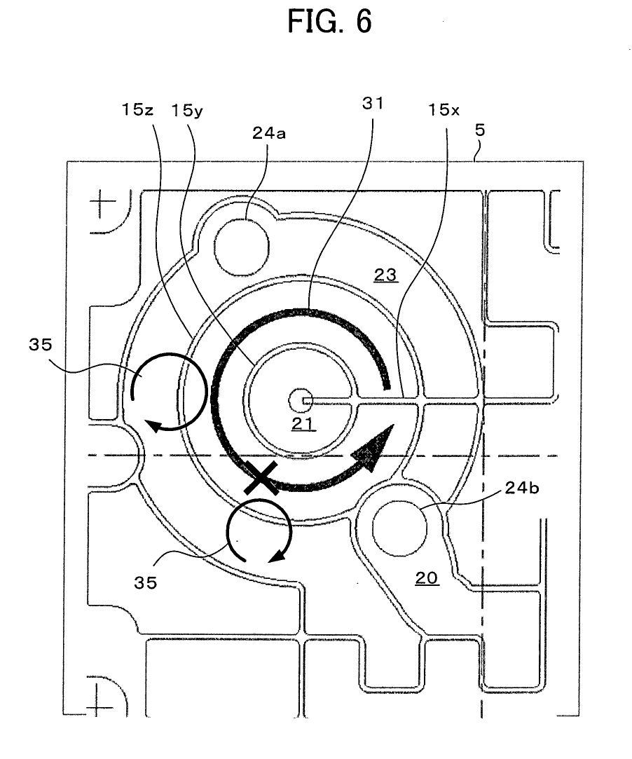

In this point, in this embodiment, the plural metallic pattern areas are formed in the vicinity of the choke coil 4 in the present invention, as shown in FIG. 6. Specifically, the metallic pattern area is divided into the plural areas in the direction of the coil current flowing in the choke coil 4 by the grooves 15. In the examples shown in FIG. 2 and FIG. 6, a groove 15x is provided to traverse the metallic pattern areas 21 to 23 in the radial direction, and thereby the metallic pattern areas 21 to 23 are divided. Namely, each of the metallic pattern areas 21 to 23 has the plane shape obtained by dividing the annular area by the groove 15x, and the loop current shown by an arrow 31 does not flow. That is, since the groove 15x has a function to cut the loop current which can be generated in the metallic pattern areas, the groove is formed to intersect with the direction of the coil current (it is not always necessary that the groove is orthogonal with respect to the direction of the coil current, but it is necessary that the groove meets the direction). Thereby, it becomes possible to suppress the generation of the loop current. In this manner, the above-mentioned problem caused due to the loop current can be prevented by dividing the metallic pattern area in the vicinity of the choke coil in the direction of the coil current of the choke coil 4.

In the examples shown in FIG. 2 and FIG. 6, the metallic pattern area in the vicinity of the choke coil is further divided in the radial direction of the choke coil 4. Namely, by circular grooves 15y and 15z, the metallic pattern area under the choke coil 4 is divided into the three concentric metallic pattern areas 21 to 23. Thereby, the small-diameter loop current shown by an arrow 35 can be also prevented, and the above-mentioned problem caused due to the loop current can be reduced.

As described above, in this embodiment, if the metallic pattern area in the vicinity of the choke coil is divided in the direction of the coil current as shown by the groove 15x, it becomes possible to prevent the generation of the loop current having the large diameter (particularly concentric with the coil current) as shown by the arrow 31. Moreover, if the metallic pattern area is divided in the radial direction from the center to the outer side of the choke coil 4 as shown by the grooves 15y and 15z, it becomes possible to prevent the generation of the loop current having the small diameter as shown by the arrow 35. In this manner, by preventing the generation of the large and small loop currents, the above-mentioned problem can be suppressed.

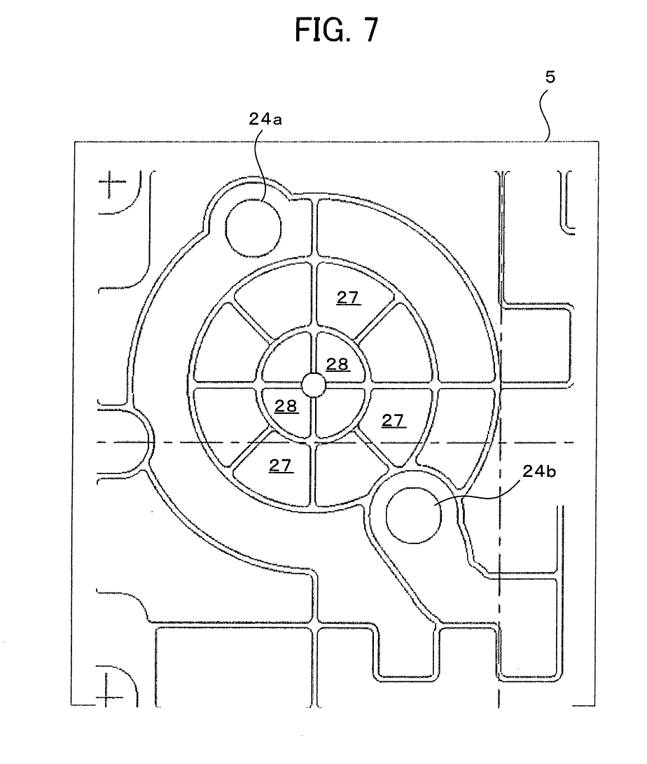

FIG. 7 shows a plan view of a printed wiring board 5a according to a modification. As understood by the above explanation, as the metallic pattern area in the vicinity of the choke coil 4 is divided into more areas in both of the loop current direction (i.e., the circumferential direction of the choke coil) and the radial direction (i.e., the direction from the center to the outer side of the choke coil), the generation of the loop current can be suppressed more. Therefore, as shown in FIG. 7, if the metallic pattern area is divided into many metallic pattern areas 27 and 28 in the circumferential direction and the radial direction of the choke coil 4, the loop current can be more efficiently suppressed.

In the above explanation, such an example that the winding direction of the wire forming the choke coil 4 is a circle is given. However, the present invention is also applicable in such a case that the winding direction of the coil is an elongated shape or a shape similar to a rectangle.

In addition, in the above embodiment, the metallic pattern area mainly positioned under the choke coil 4 is divided. However, not only the loop current under the choke coil 4 but also the loop current generated in the vicinity of the choke coil 4 may affect the choke coil. Therefore, it is preferable that the metallic pattern area is similarly divided into the plural areas not only in the metallic pattern area under the choke coil 4 but also within a certain range in the vicinity of the choke coil 4 and the generation of the loop current is suppressed.

The invention may be embodied on other specific forms without departing from the spirit or essential characteristics thereof. The present embodiments therefore to be considered in all respects as illustrative and not restrictive, the scope of the invention being indicated by the appended claims rather than by the foregoing description and all changes which come within the meaning an range of equivalency of the claims are therefore intended to embraced therein.

The entire disclosure of Japanese Patent Application No. 2006-202826 filed on Jul. 26, 2006 including the specification, claims, drawings and summary is incorporated herein by reference in its entirety.

What is claimed is:

1. A printed wiring board comprising:
a coil mounting part on which a coil is mounted; and
a metallic pattern area which is provided in a coil vicinity area including the coil mounting part,
wherein the metallic pattern area is divided into plural areas in a direction of a coil current flowing in the coil.

2. The printed wiring board according to claim 1, wherein the metallic pattern area includes grooves which intersect with the direction of the coil current and which segment the plural areas.

3. The printed wiring board according to claim 1, wherein the metallic pattern area is divided into plural areas in a direction from a center of the coil to an outer side thereof.

4. The printed wiring board according to claim 1, wherein the metallic pattern area includes a terminal area to which a terminal of the coil is conductively fixed.

5. A printed circuit board comprising:
a coil; and
a printed wiring board on which a metallic pattern area is provided in a coil vicinity area including a coil mounting part on which the coil is mounted,
wherein the metallic pattern area is divided into plural areas in a direction of a coil current flowing in the coil.
